(19) United States
(12) Patent Application Publication
(10) Pub. No.: US 2005/0116742 A1
(43) Pub. Date: Jun. 2, 2005

(54) Non-fixed oscillatory wave signal generating method and apparatus

(76) Inventor: Wen-Lin Liang, Kaohsiung Hsien (TW)

Correspondence Address: JACOBSON HOLMAN PLLC, 400 SEVENTH STREET, N.W., WASHINGTON, DC, 20004, US

(21) Appl. No.: 10/994,333

(22) Filed: Nov. 23, 2004

(30) Foreign Application Priority Data
Nov. 27, 2003 (TW) 092133387

(51) Int. Cl. H03B 21/00

(52) U.S. Cl. 327/105

(57) ABSTRACT

In a method of generating an oscillatory wave signal, a set of digitized time-domain basic wave signals are transformed into a corresponding set of frequency spectra. The set of frequency spectra are randomly processed, and are subsequently combined so as to obtain a mixed spectrum The mixed spectrum is transformed into a time-domain synthesized wave signal corresponding to the mixed spectrum. Thereafter, the synthesized wave signal is converted into an analog wave signal. An apparatus for generating the oscillatory wave signal is also disclosed.

### CROSS-REFERENCE TO RELATED APPLICATION

This application claims priority of Taiwanese Application No 092133387, filed on Nov. 27, 2003.

### BACKGROUND OF THE INVENTION

1. Field of the Invention

The invention relates to the generation of oscillatory wave signals, more particularly to a method and apparatus for generating a non-fixed oscillatory wave signal that is suitable for electrotherapeutic applications.

2. Description of the Related Art

In conventional electrotherapy, a specific oscillatory wave signal is applied to a human body for physical therapy. However, since the human body is able to adapt to the stimulus of the specific oscillatory wave signal after a period of exposure to the same, the desired therapeutic effect cannot be ensured.

### SUMMARY OF THE INVENTION

Therefore, the object of the present invention is to provide a method and apparatus for generating a non-fixed oscillatory wave signal that is suitable for application to a patient undergoing electrotherapy.

According to one aspect of the present invention, there is provided a method of generating an oscillatory wave signal. The method comprises the steps of:
a) establishing a set of digitized time-domain basic wave signals;
b) transforming the digitized time-domain basic wave signals into a corresponding set of frequency spectra;
c) randomly processing the set of frequency spectra;
d) combining the set of frequency spectra processed in step c) so as to obtain a mixed spectrum;
e) transforming the mixed spectrum into a time-domain synthesized wave signal corresponding to the mixed spectrum; and
f) converting the synthesized wave signal into an analog wave signal.

According to another aspect of the present invention, there is provided an apparatus for generating an oscillatory wave signal. The apparatus comprises:
a signal generating module for establishing a set of digitized time-domain basic wave signals;
a first transforming unit coupled to the signal generating module for transforming the digitized time-domain basic wave signals into a corresponding set of frequency spectra;
a processing unit coupled to the first transforming module for randomly processing the set of frequency spectra;
a combining module coupled to the processing unit for combining the set of frequency spectra processed by the processing unit so as to obtain a mixed spectrum;
a second transforming unit coupled to the combining module for transforming the mixed spectrum into a time-domain synthesized wave signal corresponding to the mixed spectrum; and
an output module coupled to the second transforming unit for converting the synthesized wave signal into an analog wave signal and for outputting the analog wave signal.

### BRIEF DESCRIPTION OF THE DRAWINGS

Other features and advantages of the present invention will become apparent in the following detailed description of the preferred embodiment with reference to the accompanying drawings, of which:

FIG. 1 is a schematic block diagram illustrating an apparatus for implementing the preferred embodiment of a method of generating an oscillatory wave signal according to the present invention;

FIG. 2 is a flow chart illustrating how the apparatus of FIG. 1 generates an oscillatory wave signal in accordance with the method of the preferred embodiment;

FIGS. 3a to 3c are plots of exemplary digitized time-domain basic wave signals (XG, XH, XM) established in the preferred embodiment;

FIG. 4a to 4c are plots of frequency spectra transformed from the digitized time-domain basic wave signals (XG, XH, XM) of FIGS. 3a to 3c;

FIG. 5 is a chart to illustrate how the frequency spectra of FIGS. 4a to 4c are combined in accordance with the preferred embodiment; and

FIG. 6 is a plot of a time-domain synthesized wave signal resulting from the processing of the digitized time-domain basic wave signals (XG, XH, XM) in accordance with the preferred embodiment.

### DETAILED DESCRIPTION OF THE PREFERRED EMBODIMENT

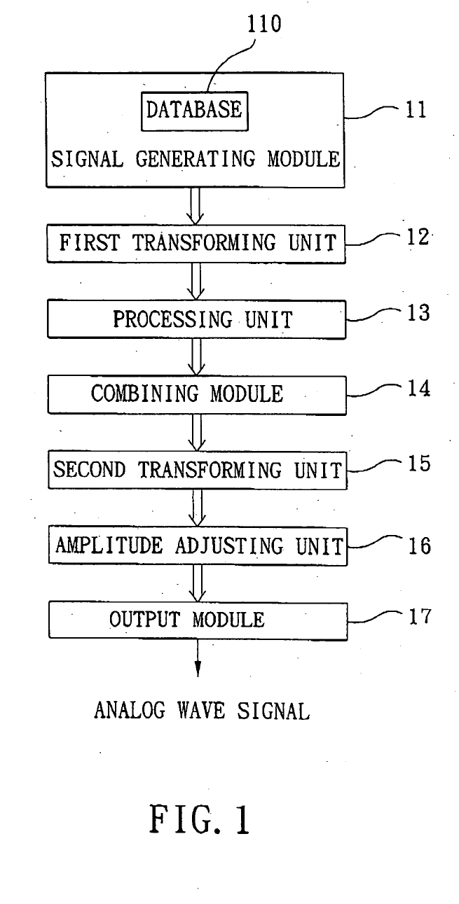

FIG. 1 illustrates an apparatus configuration for implementing the preferred embodiment of a method of generating a non-fixed oscillatory wave signal according to the present invention. The apparatus includes a signal generating module 11, a first transforming unit 12, a processing unit 13, a combining module 14, a second transforming unit 15, an amplitude adjusting unit 16, and an output module 17.

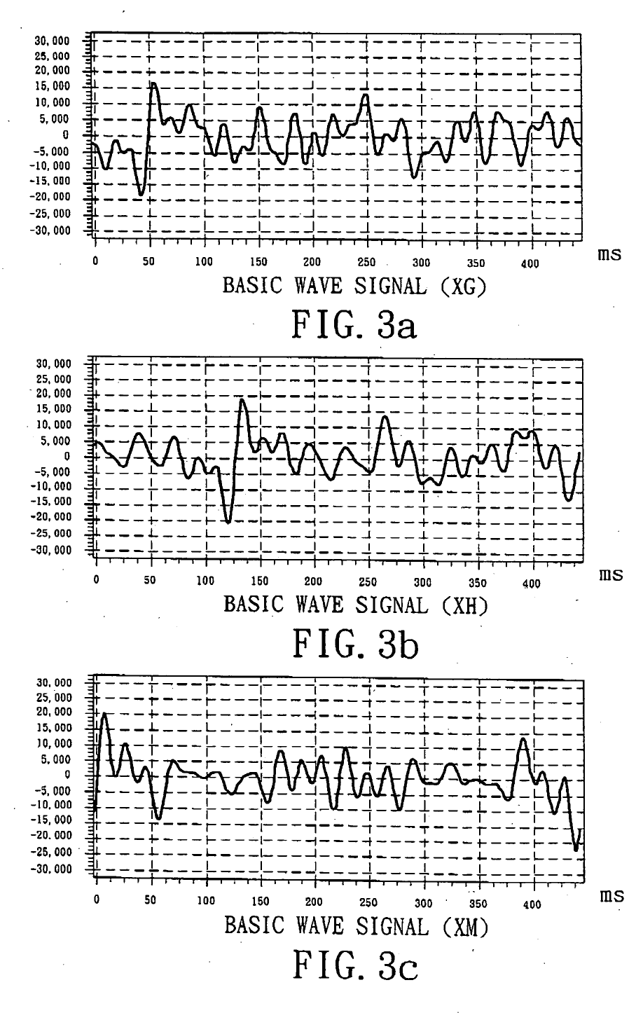

The signal generating module 11 is operable so as to establish a set of digitized time-domain basic wave signals in a trial-and-error manner. In this embodiment, the set of digitized time-domain basic wave signals, which can be stored in a database 110 built-in the signal generating modules 11, includes three digitized time-domain basic wave signals (XG, XH, XM) that are suitable for application to a patient undergoing electrotherapy, as shown in FIGS. 3a to 3c.

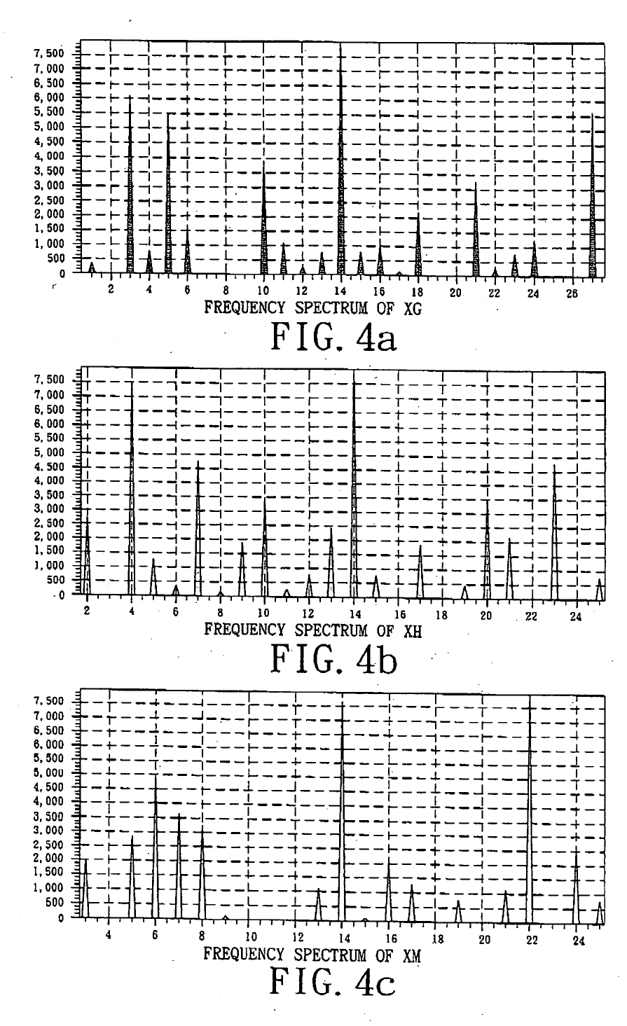

The first transforming unit 12 is coupled to the signal generating module 11, and is operable so as to transform the digitized time-domain basic wave signals (XG, XH, XM) into corresponding frequency spectra, as shown in FIGS. 4a to 4c. In this embodiment, the first transforming unit 12 performs Fast Fourier Transform to obtain the frequency spectra. Each of the frequency spectra includes a baseband spectral component and a plurality of harmonic spectral components. The frequencies of the harmonic spectral components are determined according to the following Equation 1:
fₙ=fₒ+fᵢ×n (Equation 1)
where fₒ denotes the frequency of the baseband spectral component, fₙ denotes the frequency of the n^{th} harmonic spectral component, and fᵢ denotes the frequency difference between the baseband spectral component and the first harmonic spectral component or between adjacent ones of the harmonic spectral components, where “n” is a natural number, and where fₙ, fₒ and fᵢ are positive real numbers.

The processing unit 13 is coupled to the first transforming module 12, and is operable so as to randomly process the set of frequency spectra. In this embodiment, the processing unit 13 randomly processes the frequency spectra by multiplying a frequency scale of each of the frequency spectra by a random natural number chosen independently of those used to process other ones of the frequency spectra. In this example, the random natural number for each of the frequency spectra is equal to 1.

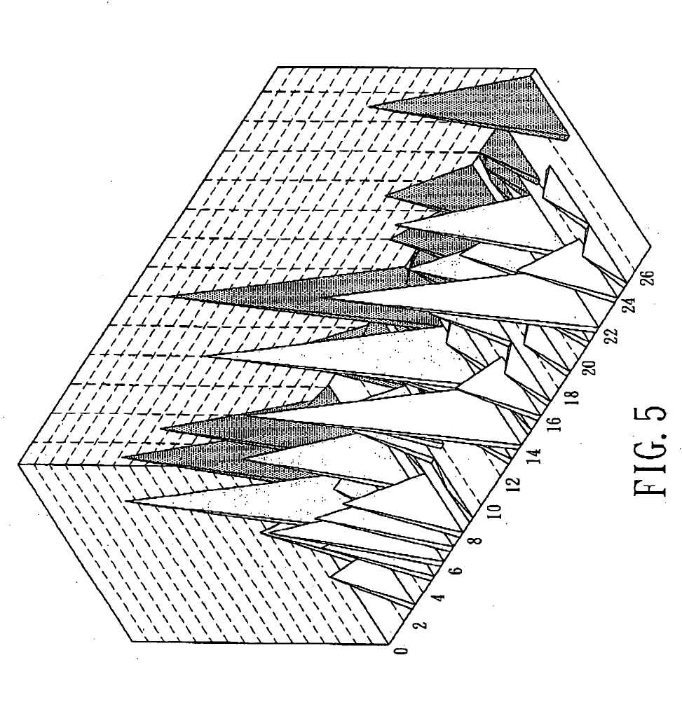

The combining module 14 is coupled to the processing unit 13 and is operable so as to combine the frequency spectra processed by the processing unit 13, thereby resulting in a mixed spectrum, as shown in FIG. 5.

The second transforming unit 15 is coupled to the combining module 14, and is operable so as to transform the mixed spectrum into a time-domain synthesized wave signal. In this embodiment, the second transforming unit 15 performs Inverse Fast Fourier Transform to obtain the synthesized wave signal.

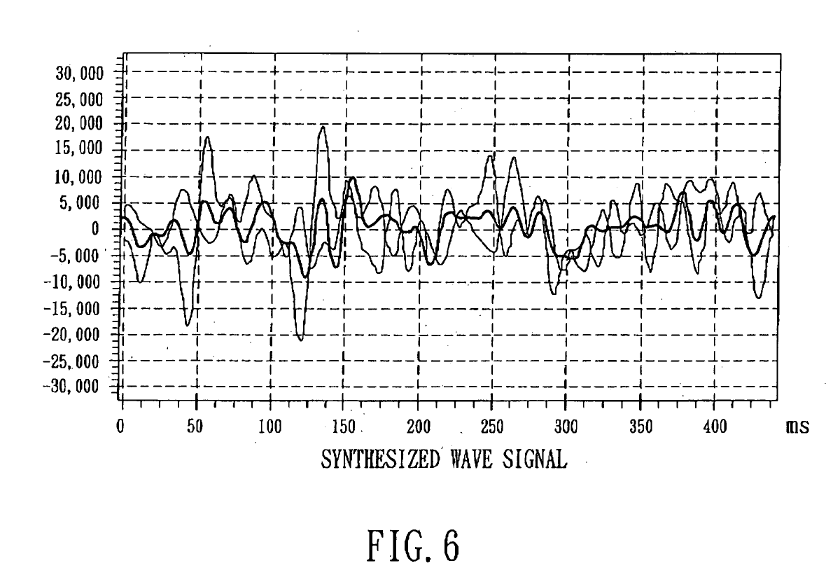

The amplitude adjusting unit 16 is coupled to the second transforming unit 15, and is operable so as to adjust amplitudes of the synthesized wave signal such that the latter is suitable for application to a human body, as shown in FIG. 6. In this embodiment, the amplitude adjusting unit 16 divides each of the amplitudes of the synthesized wave signal by an average of the amplitudes of the synthesized wave signal

The output module 17 is coupled to the amplitude adjusting unit 16, and is operable so as to convert the synthesized wave signal adjusted by the amplitude adjusting unit 16 into an analog wave signal and so as to output the analog wave signal in the form of small current and low voltage via an electrode (not shown) In this embodiment, the analog wave signal outputted by the output module 17 is the non-fixed oscillatory wave signal, and is suitable for application to a patient undergoing electrotherapy.

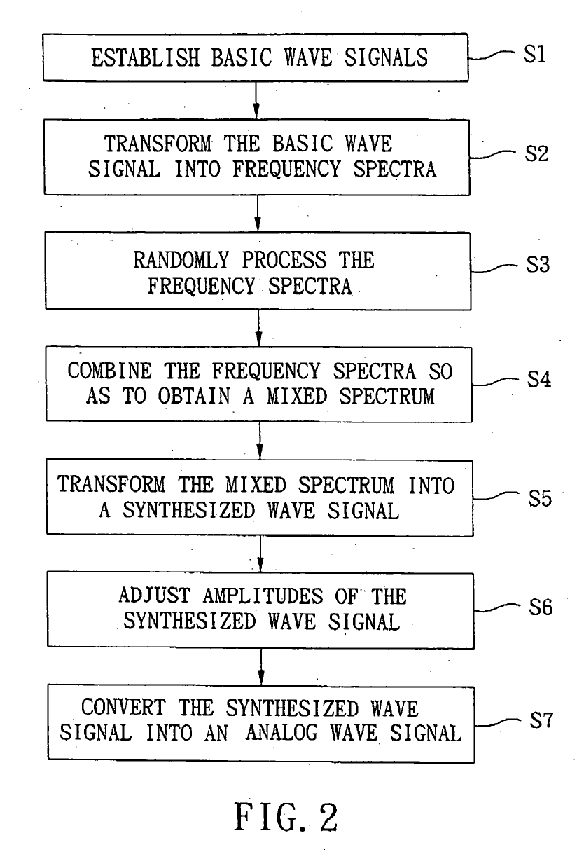

Referring to FIG. 2, there is shown a flow chart to illustrate how the apparatus generates the non-fixed oscillatory wave signal in accordance with the method of the preferred embodiment. In step S1, the signal generating module 11 is operable so as to establishe the set of digitized time-domain basic wave signals (XG, XH, XM). In step S2, the first transforming unit 12 transforms the digitized time-domain basic wave signals (XG, XH, XM) into the corresponding set of frequency spectra. In step S3, the processing unit 13 randomly processes the set of frequency spectra. In step S4, the combining unit 14 combines the set of frequency spectra processed by the processing unit 13 so as to obtain the mixed spectrum. In step S5, the second transforming unit 15 transforms the mixed spectrum into a time-domain synthesized wave signal corresponding to the mixed spectrum. In step S6, the amplitude adjusting unit 16 adjusts the amplitudes of the synthesized wave signal so as to be suitable for application to a human body. In step S7, the output module 17 converts the synthesized wave signal adjusted by the amplitude adjusting unit 16 into the analog wave signal (i.e., the non-fixed oscillatory wave signal that is suitable for a patient undergoing electrotherapy).

To sum up, this invention discloses the generation of non-fixed oscillatory wave signals for application to a patient undergoing electrotherapy. Because of the non-fixed characteristics of the oscillatory wave signal, the human body is unable to adapt to its stimulus after a period of exposure to the same, thereby ensuring the desired therapeutic effect.

While the present invention has been described in connection with what is considered the most practical and preferred embodiment, it is understood that this invention is not limited to the disclosed embodiment but is intended to cover various arrangements included within the spirit and scope of the broadest interpretation so as to encompass all such modifications and equivalent arrangements.

1. A method of generating an oscillatory wave signal, comprising the steps of:
a) establishing a set of digitized time-domain basic wave signals;
b) transforming the digitized time-domain basic wave signals into a corresponding set of frequency spectra;
c) randomly processing the set of frequency spectra;
d) combining the set of frequency spectra processed in step c) so as to obtain a mixed spectrum;
e) transforming the mixed spectrum into a time-domain synthesized wave signal corresponding to the mixed spectrum; and
f) converting the synthesized wave signal into an analog wave signal.

2. The method as claimed in claim 1, wherein the digitized time-domain basic wave signals are suitable for application to a patient undergoing electrotherapy.

3. The method as claimed in claim 1, wherein the analog wave signal generated instep f) is the oscillatory wave signal and is suitable for application to a patient undergoing electrotherapy.

4. The method as claimed in claim 1, wherein the set of frequency spectra are randomly processed in step c) by multiplying a frequency scale of each of the set of frequency spectra by a random natural number chosen independently of those used to process other ones of the frequency spectra.

5. The method as claimed in claim 2, further comprising, prior to step f), the step of e′) adjusting amplitudes of the synthesized wave signal so as to be suitable for application to a human body.

6. The method as claimed in claim 5, wherein, in step e′), each of the amplitudes of the synthesized wave signal is divided by an average of the amplitudes of the synthesized wave signal.

7. The method as claimed in claim 1, wherein step b) is performed using Fast Fourier Transform.

8. The method as claimed in claim 1, wherein step e) is performed using Inverse Fast Fourier Transform.

9. An apparatus for generating an oscillatory wave signal, comprising:
a signal generating module for establishing a set of digitized time-domain basic wave signals;
a first transforming unit coupled to said signal generating module for transforming the digitized time-domain basic wave signals into a corresponding set of frequency spectra;
a processing unit coupled to said first transforming module for randomly processing the set of frequency spectra;
a combining module coupled to said processing unit for combining the set of frequency spectra processed by said processing unit so as to obtain a mixed spectrum;
a second transforming unit coupled to said combining module for transforming the mixed spectrum into a time-domain synthesized wave signal corresponding to the mixed spectrum; and
an output module coupled to said second transforming unit for converting the synthesized wave signal into an analog wave signal and for outputting the analog wave signal.

10. The apparatus as claimed in claim 9, wherein the digitized time-domain basic wave signals are suitable for application to a patient undergoing electrotherapy.

11. The apparatus as claimed in claim 9, wherein the analog wave signal outputted by said output module is the oscillatory wave signal and is suitable for application to a patient undergoing electrotherapy.

12. The apparatus as claimed in claim 9, wherein said processing unit randomly processes the set of frequency spectra are by multiplying a frequency scale of each of the set of frequency spectra by a random natural number chosen independently of those used to process other ones of the frequency spectra.

13. The apparatus as claimed in claim 10, further comprising an amplitude adjusting unit coupled to said second transforming unit and said output module for adjusting amplitudes of the synthesized wave signal so that the synthesized wave signal is suitable for application to a human body.

14. The apparatus as claimed in claim 13, wherein said amplitude adjusting unit divides each of the amplitudes of the synthesized wave signal by an average of the amplitudes of the synthesized wave signal.

15. The apparatus as claimed in claim 9, wherein said first transforming unit performs Fast Fourier Transform to obtain the set of frequency spectra.

16. The apparatus as claimed in claim 9, wherein said second transforming unit performs Inverse Fast Fourier Transform to obtain the synthesized wave signal.
